(19) United States
(12) Patent Application Publication
(10) Pub. No.: US 2025/0087271 A1
(43) Pub. Date: Mar. 13, 2025

(54) SEMICONDUCTOR MEMORY DEVICE AND METHOD OF OPERATING THE SEMICONDUCTOR MEMORY DEVICE

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 18/411,348

(22) Filed: Jan. 12, 2024

(30) Foreign Application Priority Data
Sep. 7, 2023 (KR) 10-2023-0118857

(51) Int. Cl. G11C 16/10; G11C 16/04; G11C 16/16

(52) U.S. Cl. CPC G11C 16/102; G11C 16/0433; G11C 16/16

(57) ABSTRACT

Provided herein is a semiconductor memory device and a method of operating the same. The semiconductor memory device includes a first string group including at least one first memory string and a second string group including at least one second memory string, each string connected in parallel between the bit line and the source line, wherein the at least one first memory string and the at least one second memory string each include at least one down source select transistor, at least one first up source select transistor, and at least one second up source select transistor, and the at least one first up source select transistor of the at least one first memory string is programmed to a first state, and the at least one first up source select transistor of the at least one second memory string is programmed to a second state different from the first state.

### CROSS-REFERENCE TO RELATED APPLICATION

The present application claims priority under 35 U.S.C. § 119 (a) to Korean patent application number 10-2023-0118857 filed on Sep. 7, 2023, in the Korean Intellectual Property Office, the entire disclosure of which is incorporated by reference herein.

### BACKGROUND

### 1. Technical Field

Various embodiments of the present disclosure generally relate to an electronic device, and more particularly to a semiconductor memory device and a method of operating the semiconductor memory device.

### 2. Related Art

A semiconductor memory device may be formed to have a two-dimensional (2D) structure in which strings are horizontally arranged on a semiconductor substrate, or may be formed to have a three-dimensional (3D) structure in which strings are vertically stacked on a semiconductor substrate. As the memory device having a 2D structure is reaching its physical scaling limit (i.e., limit in the degree of integration), 3D memory devices including a plurality of memory cells vertically stacked on a semiconductor substrate are produced.

### SUMMARY

An embodiment of the present disclosure may provide for a semiconductor memory device. The semiconductor memory device may include first string group including at least one first memory string connected in parallel between a bit line and a source line, and a second string group including at least one second memory string connected in parallel between the bit line and the source line, wherein the at least one first memory string and the at least one second memory string each include at least one down source select transistor, at least one first up source select transistor, and at least one second up source select transistor, and wherein the at least one first up source select transistor of the at least one first memory string is programmed to a first state, and the at least one first up source select transistor of the at least one second memory string is programmed to a second state.

An embodiment of the present disclosure may provide for a method of operating a semiconductor memory device including a plurality of first memory strings and a plurality of second memory strings, each of the first and second memory strings are connected in parallel between a bit line and a source line, each of the first and second memory strings including at least one first up source select transistor and at least one second up source select transistor which are connected in series. The method may include programming the at least one second up source select transistor of the plurality of first memory strings to a first state, programming the at least one second up source select transistor of the plurality of second memory strings to a second state, programming the at least one first up source select transistor of the plurality of first memory strings to the second state, and programming the at least one first up source select transistor of the plurality of second memory strings to the first state, wherein the at least one first up source select transistor of the plurality of first memory strings and the at least one first up source select transistor of the plurality of second memory strings are programed based on a first up source select line, and wherein the at least one second up source select transistor of the plurality of first memory strings and the at least one second up source select transistor of the plurality of second memory strings are programed based on a second up source select line.

An embodiment of the present disclosure may provide for a semiconductor memory device. The semiconductor memory device may include a plurality of first memory strings connected in parallel between a bit line and a source line, and a plurality of second memory strings connected in parallel between the bit line and the source line, wherein each of the plurality of first memory strings and the plurality of second memory strings includes at least one down source select transistor, at least one first up source select transistor, and at least one second up source select transistor which are connected in series, wherein at least one down source select transistor of the plurality of first memory strings and at least one down source select transistor of the plurality of second memory strings share one down source select line, and wherein at least one first up source select transistor of the plurality of first memory strings shares a first up source select line, and at least one first up source select transistor of the plurality of second memory strings shares a second up source select line.

An embodiment of the present disclosure may provide for a semiconductor memory device. The semiconductor memory device may include first to fourth memory strings connected in parallel between a bit line and a source line, wherein each of the first to fourth memory strings includes at least one down source select transistor, at least one first up source select transistor, and at least one second up source select transistor which are connected in series, the down source select transistors of the first memory string and the second memory string share an even down source select line, and the down source select transistors of the third memory string and the fourth memory string shares an odd down source select line, the first up source select transistors of the first to fourth memory strings are controlled by a first up source select line, and the second up source select transistors of the first to fourth memory strings are controlled by a second up source select line.

### BRIEF DESCRIPTION OF THE DRAWINGS

FIG. 1 is a block diagram illustrating a semiconductor memory device according to an embodiment of the present disclosure.

FIG. 2 is a diagram illustrating an embodiment of a memory cell array of FIG. 1.

FIG. 3 is a circuit diagram for explaining a memory block according to an embodiment of the present disclosure.

FIG. 4 is a circuit diagram for explaining a memory block according to an embodiment of the present disclosure.

FIG. 5 is a flowchart for explaining a program operation on source select transistors according to an embodiment of the present disclosure.

FIGS. 6A and 6B are diagrams for explaining voltages applied during a program operation on source select transistors according to an embodiment of the present disclosure.

FIG. 7 is a diagram for explaining the states of a plurality of source select transistor groups after the program operation is performed on the source select transistors.

FIG. 8 is a circuit diagram for explaining a memory block according to an embodiment of the present disclosure.

FIG. 9 is a circuit diagram for explaining a memory block according to an embodiment of the present disclosure.

FIG. 10 is a circuit diagram for explaining a memory block according to an embodiment of the present disclosure.

FIG. 11 is a diagram illustrating a solid state drive (SSD) system to which a semiconductor memory device according to an embodiment of the present disclosure is applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

Various embodiments of the present disclosure are directed to a semiconductor memory device and a method of operating the semiconductor memory device, which can improve the reliability of a read operation by differently coding source select transistors included in a plurality of memory strings for respective string groups.

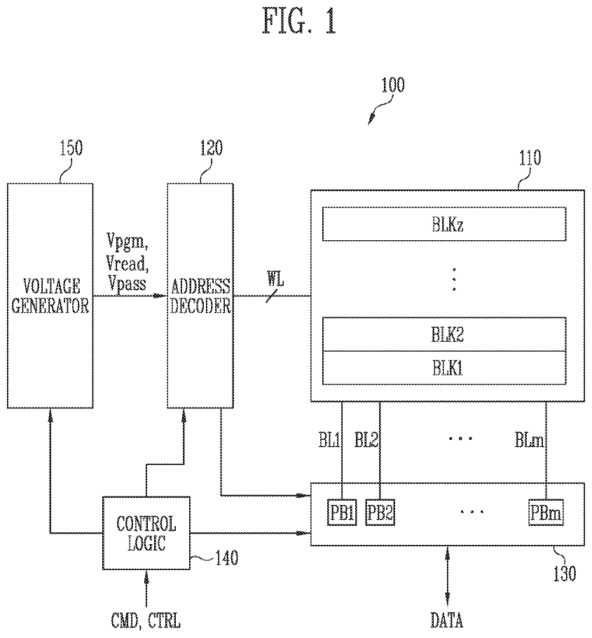

FIG. 1 is a block diagram illustrating a semiconductor memory device according to an embodiment of the present disclosure.

Referring to FIG. 1, a semiconductor memory device 100 may include a memory cell array 110, an address decoder 120, a read and write circuit 130, control logic 140, and a voltage generator 150. The control logic 140 may be implemented as hardware, software, or a combination of hardware and software. For example, the control logic 140 may be a control logic circuit operating in accordance with an algorithm and/or a processor executing control logic code.

The memory cell array 110 may include a plurality of memory blocks BLK1 to BLKz. The memory blocks BLK1 to BLKz are coupled to the address decoder 120 through word lines WL. The plurality of memory blocks BLK1 to BLKz are coupled to the read and write circuit 130 through bit lines BL1 to BLm. Each of the memory blocks BLK1 to BLKz includes a plurality of memory cells. In an embodiment, the plurality of memory cells may be nonvolatile memory cells, and may be implemented as nonvolatile memory cells having a vertical channel structure. The memory cell array 110 may be implemented as a memory cell array having a two-dimensional (2D) structure. In an embodiment, the memory cell array 110 may be implemented as a memory cell array having a three-dimensional (3D) structure. Meanwhile, each of the memory cells included in the memory cell array may store at least 1 bit of data. In an embodiment, each of the memory cells included in the memory cell array 110 may be a single-level cell (SLC), which stores 1 bit of data. In an embodiment, each of the memory cells included in the memory cell array 110 may be a multi-level cell (MLC), which stores 2 bits of data. In an embodiment, each of the memory cells included in the memory cell array 110 may be a triple-level cell (TLC), which stores 3 bits of data. In an embodiment, each of the memory cells included in the memory cell array 110 may be a quad-level cell, which stores 4 bits of data. In various embodiments, the memory cell array 110 may include a plurality of memory cells, each of which stores 5 or more bits of data.

The address decoder 120, the read and write circuit 130, the control logic 140, and the voltage generator 150 operate as a peripheral circuit for driving the memory cell array 110. The address decoder 120 is coupled to the memory cell array 110 through the word lines WL. The address decoder 120 may be operated under the control of the control logic 140. The address decoder 120 receives addresses through an input/output buffer (not illustrated) provided in the semiconductor memory device 100.

The address decoder 120 may decode a block address among the received addresses. The address decoder 120 selects at least one memory block based on the decoded block address. When a read voltage apply operation is performed during a read operation, the address decoder 120 may apply a read voltage Vread, generated by the voltage generator 150, to a selected word line of a selected memory block and apply a pass voltage Vpass to the remaining word lines, that is, unselected word lines. Further, during a program verify operation, the address decoder 120 may apply a verify voltage, generated by the voltage generator 150, to a selected word line of a selected memory block and apply the pass voltage Vpass to the remaining word lines, that is, unselected word lines. Furthermore, during a program operation, the address decoder 120 may apply a program voltage Vpgm, generated by the voltage generator 150, to a selected word line of a selected memory block, and may apply the pass voltage Vpass to the remaining word lines, that is, unselected word lines. Further, during a program operation on the source select transistors, the address decoder 120 may apply the program voltage Vpgm to a selected source select line coupled to selected source select transistors and apply the pass voltage Vpass to a source select line coupled to unselected source select transistors.

The address decoder 120 may decode a column address among the received addresses. The address decoder 120 may transmit the decoded column address to the read and write circuit 130.

The read and program operations of the semiconductor memory device 100 are each performed on a page basis. The addresses, received when each of the read and program operations is requested, may include a block address, a row address, and a column address. The address decoder 120 may select one memory block and one word line in accordance with the block address and the row address. The column address may be decoded by the address decoder 120, and may then be provided to the read and write circuit 130.

The address decoder 120 may include a block decoder, a row decoder, a column decoder, an address buffer, etc.

The read and write circuit 130 includes a plurality of page buffers PB1 to PBm. The read and write circuit 130 may operate as a “read circuit” during a read operation on the memory cell array 110 and as a “write circuit” during a write operation. The plurality of page buffers PB1 to PBm are coupled to the memory cell array 110 through the bit lines BL1 to BLm. In order to sense threshold voltages of the memory cells during a read operation or a program verify operation, the page buffers PB1 to PBm may continuously supply a sensing current to the bit lines coupled to the memory cells while each of the page buffers PB1 to PBm senses, through a sensing node, a change in the amount of flowing current depending on the program state of a corresponding memory cell and latches it as sensing data. The read and write circuit 130 is operated in response to page buffer control signals output from the control logic 140.

During a read operation, the read and write circuit 130 may sense data stored in the memory cells and temporarily store read data, and may then output data DATA to the input/output buffer (not shown) of the semiconductor memory device 100. In an embodiment, the read and write circuit 130 may include a column select circuit or the like as well as the page buffers (or page registers).

The control logic 140 may be electrically coupled to the address decoder 120, the read and write circuit 130, and the voltage generator 150. The control logic 140 may receive a command CMD and a control signal CTRL through the input/output buffer (not shown) of the semiconductor memory device 100. The control logic 140 may control the overall operation of the semiconductor memory device 100 in response to the control signal CTRL. Also, the control logic 140 may output a control signal for controlling a precharge potential level at the sensing node of the plurality of page buffers PB1 to PBm. The control logic 140 may control the read and write circuit 130 to perform a read operation, a program operation, or an erase operation on the memory cell array 110.

The voltage generator 150 may generate the read voltage Vread and the pass voltage Vpass in response to the control signal output from the control logic 140 during a read operation. Further, the voltage generator 150 may generate the program voltage Vpgm and the pass voltage Vpass in response to the control signal output from the control logic 140 during the program operation on the memory cells or the program operation on the source select transistors.

The voltage generator 150 may include a plurality of pumping capacitors for receiving an internal supply voltage to generate a plurality of voltages having various voltage levels, and may generate a plurality of voltages by selectively enabling the plurality of pumping capacitors under the control of the control logic 140.

The address decoder 120, the read and write circuit 130, and the voltage generator 150 may function as the peripheral circuit which performs a read operation, a program operation, and an erase operation on the memory cell array 110. The peripheral circuit may perform a read operation, a program operation, and an erase operation on the memory cell array 110 under the control of the control logic 140.

Furthermore, the control logic 140 may control the peripheral circuit to perform a program operation on the source select transistors included in the selected memory block before the program operation on the memory cell array 110 is performed. A detailed description of the program operation on the source select transistors will be made later.

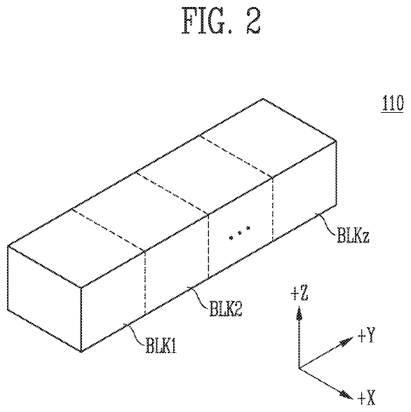

FIG. 2 is a diagram illustrating an embodiment of the memory cell array of FIG. 1.

Referring to FIG. 2, the memory cell array 110 includes a plurality of memory blocks BLK1 to BLKz. Each of the memory blocks may have a three-dimensional (3D) structure. Each of the memory blocks may include a plurality of memory cells stacked on a substrate. The plurality of memory cells are arranged in +X, +Y, and +Z directions.

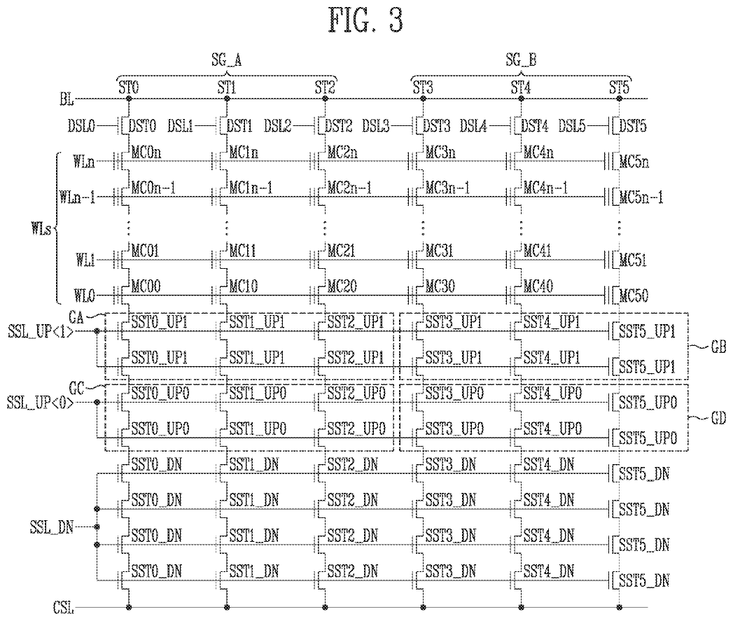

FIG. 3 is a circuit diagram for explaining a memory block according to an embodiment of the present disclosure.

Referring to FIG. 3, the memory block may include a plurality of memory strings ST0 to ST5 connected in parallel between one bit line BL and a common source line CSL.

Each of the plurality of memory strings ST0 to ST5 may include at least one drain select transistor, a plurality of memory cells, at least one first up source select transistor, at least one second up source select transistor, and at least one down source select transistor which are connected in series.

The plurality of memory strings ST0 to ST5 may be configured to have a similar structure.

For example, the memory string ST0 may include a drain select transistor DST0, a plurality of memory cells MC00 to MC0n, second up source select transistors SST0_UP1, first up source select transistors SST0_UP0, and down source select transistors SST0_DN which are connected in series between the bit line BL and the common source line CSL. A gate of the drain select transistor DST0 may be electrically coupled to a drain select line DSL0 and gates of the plurality of memory cells MC00 to MC0n may be electrically coupled to a plurality of word lines WLs (WL0 to WLn). Gates of the second up source select transistors SST0_UP1 may be electrically coupled in common to one second up source select line SSL_UP<1>, gates of the first up source select transistors SST0_UP0 may be electrically coupled in common to one first up source select line SSL_UP<0>, and gates of the down source select transistors SST0_DN may be electrically coupled to one down source select line SSL_DN.

Also, the memory string ST1 may include a drain select transistor DST1, a plurality of memory cells MC10 to MC1n, second up source select transistors SST1_UP1, first up source select transistors SST1_UP0, and down source select transistors SST1_DN which are connected in series between the bit line BL and the common source line CSL. A gate of the drain select transistor DST1 may be electrically coupled to a drain select line DSL1, gates of the plurality of memory cells MC10 to MC1n may be electrically coupled to the plurality of word lines WLs (WL0 to WLn), gates of the second up source select transistors SST1_UP1 may be electrically coupled in common to the one second up source select line SSL_UP<1>, gates of the first up source select transistors SST1_UP0 may be electrically coupled in common to the one first up source select line SSL_UP<0>, and gates of the down source select transistors SST1_DN may be electrically coupled to the one down source select line SSL_DN.

The memory string ST2 may include a drain select transistor DST2, a plurality of memory cells MC20 to MC2n, second up source select transistors SST2_UP1, first up source select transistors SST2_UP0, and down source select transistors SST2_DN which are connected in series between the bit line BL and the common source line CSL. A gate of the drain select transistor DST2 may be electrically coupled to a drain select line DSL2, gates of the plurality of memory cells MC20 to MC2n may be electrically coupled to the plurality of word lines WLs (WL0 to WLn), gates of the second up source select transistors SST2_UP1 may be electrically coupled in common to the one second up source select line SSL_UP<1>, gates of the first up source select transistors SST2_UP0 may be electrically coupled in common to the one first up source select line SSL_UP<0>, and gates of the down source select transistors SST2_DN may be electrically coupled to the one down source select line SSL_DN.

The memory string ST3 may include a drain select transistor DST3, a plurality of memory cells MC30 to MC3n, second up source select transistors SST3_UP1, first up source select transistors SST3_UP0, and down source select transistors SST3_DN which are connected in series between the bit line BL and the common source line CSL. A gate of the drain select transistor DST3 may be electrically coupled to a drain select line DSL3, gates of the plurality of memory cells MC30 to MC3n may be electrically coupled to a plurality of word lines WLs (WL0 to WLn), gates of the second up source select transistors SST3_UP1 may be electrically coupled in common to one second up source select line SSL_UP<1>, gates of the first up source select transistors SST3_UP0 may be electrically coupled in common to one first up source select line SSL_UP<0>, and gates of the down source select transistors SST3_DN may be electrically coupled to one down source select line SSL_DN.

The memory string ST4 may include a drain select transistor DST4, a plurality of memory cells MC40 to MC4n, second up source select transistors SST4_UP1, first up source select transistors SST4_UP0, and down source select transistors SST4_DN which are connected in series between the bit line BL and the common source line CSL. A gate of the drain select transistor DST4 may be electrically coupled to a drain select line DSL4, gates of the plurality of memory cells MC40 to MC4n may be electrically coupled to a plurality of word lines WLs (WL0 to WLn), gates of the second up source select transistors SST4_UP1 may be electrically coupled in common to one second up source select line SSL_UP<1>, gates of the first up source select transistors SST4_UP0 may be electrically coupled in common to one first up source select line SSL_UP<0>, and gates of the down source select transistors SST4_DN may be electrically coupled to one down source select line SSL_DN.

The memory string ST5 may include a drain select transistor DST5, a plurality of memory cells MC50 to MC5n, second up source select transistors SST5_UP1, first up source select transistors SST5_UP0, and down source select transistors SST5_DN which are connected in series between the bit line BL and the common source line CSL. A gate of the drain select transistor DST5 may be electrically coupled to a drain select line DSL5, gates of the plurality of memory cells MC50 to MC5n may be electrically coupled to a plurality of word lines WLs (WL0 to WLn), gates of the second up source select transistors SST5_UP1 may be electrically coupled in common to one second up source select line SSL_UP<1>, gates of the first up source select transistors SST5_UP0 may be electrically coupled in common to one first up source select line SSL_UP<0>, and gates of the down source select transistors SST5_DN may be electrically coupled to one down source select line SSL_DN.

As described above, the plurality of memory strings ST0 to ST5 may be electrically coupled to different drain select lines DSL0 to DSL5, respectively, and may be electrically coupled in common to the plurality of word lines WLs (WL0 to WLn), the second up source select line SSL_UP<1>, the first up source select line SSL_UP<0>, and the down source select line SSL_DN. That is, the plurality of memory strings ST0 to ST5 may correspond to different drain select lines DSL0 to DSL5, respectively, and may share the plurality of word lines WLs (WL0 to WLn), the second up source select line SSL_UP<1>, the first up source select line SSL_UP<0>, and the down source select line SSL_DN.

In an embodiment of the present disclosure, some of the plurality of memory strings adjacent to each other may be defined as one string group. For example, the memory strings ST0, ST1, and ST2 may be defined as a first string group SG_A, and the memory strings ST3, ST4, and ST5 may be defined as a second string group SG_B. As another example, the string group may include a single memory string. Further, the string group may include at least two memory strings spaced apart from each other.

Further, the second up source select transistors SST0_UP1, SST1_UP1, and SST2_UP1 included in the first string group SG_A may be defined as a first coding group GA, the second up source select transistors SST3_UP1, SST4_UP1, and SST5_UP1 included in the second string group SG_B may be defined as a second coding group GB, the first up source select transistors SST0_UP0, SST1_UP0, and SST2_UP0 included in the first string group SG_A may be defined as a third coding group GC, and the first up source select transistors SST3_UP0, SST4_UP0, and SST5_UP0 included in the second string group SG_B may be defined as a fourth coding group GD.

The second up source select transistors SST0_UP1, SST1_UP1, and SST2_UP1 of the first coding group GA and the second up source select transistors SST3_UP1, SST4_UP1, and SST5_UP1 of second coding group GB may be programmed to different states from each other. For example, the second up source select transistors SST0_UP1, SST1_UP1, and SST2_UP1 of the first coding group GA may be programmed to the first state corresponding to data “1”, and the second up source select transistors SST3_UP1, SST4_UP1, and SST5_UP1 of the second coding group GB may be programmed to a second state corresponding to data “0”. For example, the first state corresponding to data “1” may be defined as an erase state in which a threshold voltage is lower than a set voltage level (e.g., the read voltage level), and the second state corresponding to data “O” may be defined as a program state in which the threshold voltage is equal to or higher than the set voltage level.

The first up source select transistors SST0_UP0, SST1_UP0, and SST2_UP0 of the third coding group GC and the first up source select transistors SST3_UP0, SST4_UP0, and SST5_UP0 of the fourth coding group GD may be programmed to different states from each other. For example, the first up source select transistors SST0_UP0, SST1_UP0, and SST2_UP0 of the third coding group GC may be programmed to the second state corresponding to data “0”, and the first up source select transistors SST3_UP0, SST4_UP0, and SST5_UP0 of the fourth coding group GD may be programmed to the first state corresponding to data “1”.

Accordingly, a coding data value of the second up source select transistors and the first up source select transistors of the memory strings ST0, ST1, and ST2 of the first string group SG_A may have a value of “10”, and a coding data value of the second up source select transistors and the first up source select transistors of the memory strings ST3, ST4, and ST5 of the second string group SG_B may have a value of “01”. That is, the coding data value of the first and third coding groups is “10” and the coding data value of the second and fourth coding groups is “01”. Further, the second up source select transistors SST0_UP1-SST5_UP1 and the first up source select transistors SST0_UP0-SST5_UP0 may be programmed such that respective string groups have different coding data values.

As described above, although the first up source select transistors SST0_UP0, SST1_UP0, and SST2_UP0 of the first string group SG_A and the first up source select transistors SST3_UP0, SST4_UP0, and SST5_UP0 of the second string group SG_B, may share the first up source select line SSL_UP<0> in common, and the second up source select transistors SST0_UP1, SST1_UP1, and SST2_UP1 of the first string group SG_A and the second up source select transistors SST3_UP1, SST4_UP1, and SST5_UP1 of the second string group SG_B may share the common second up source select line SSL_UP<1> in common, the second up source select transistors SST0_UP1 to SST5_UP1 and the first up source select transistors SST0_UP0 to SST5_UP1 may be programmed such that respective string groups have different coding data values. As a result, one string group may be selectively activated by controlling signals applied to the first up source select line SSL_UP<0> and the second up source select line SSL_UP<1> during a read operation. For example, the first coding group GA and the second coding group GB may be programed into the first and second states which are different based on a voltage level of the second source select line SSL_UP<0>. Further, the first coding group GA the third coding group GC may be differently programed into the first and second states based on voltage levels of the first and second source select lines SSL_UP<0> and SSL_UP<1>. In various embodiments, the up source select transistors electrically coupled to the source select line arranged adjacent to the word line WL0 are referred to the second up source select transistors and the up source select transistors electrically coupled to the source selection line arranged adjacent to the down select line SSL_DN are referred to the first up source select transistor. However, the embodiments of the present disclosure are not limit to this, the up source select transistors electrically coupled to the source select line arranged adjacent to the word line WL0 may be referred to a first up source select transistors and the up source select transistors electrically coupled to the source selection line arranged adjacent to the down select line SSL_DN may be referred to the second up source select transistor.

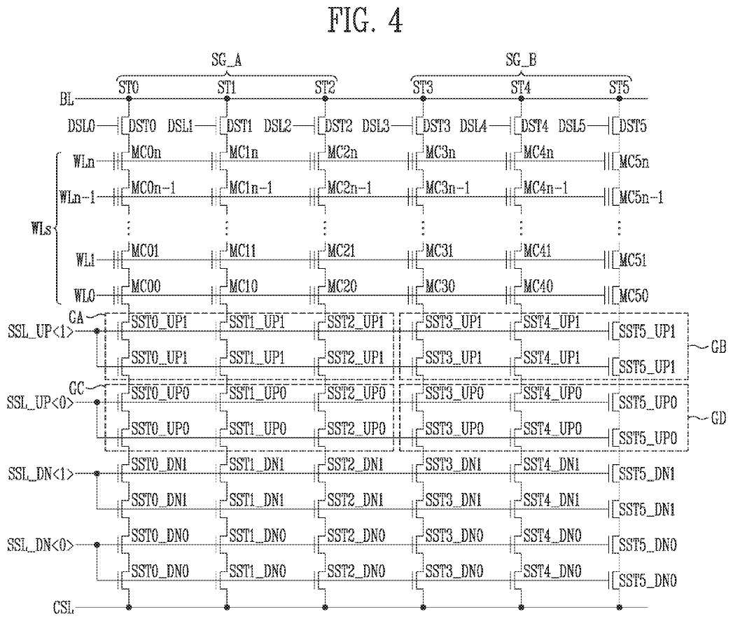

FIG. 4 is a circuit diagram for explaining a memory block according to an embodiment of the present disclosure.

Referring to FIG. 4, the memory block may include a plurality of memory strings ST0 to ST5 connected in parallel between one bit line BL and a common source line CSL.

Each of the plurality of memory strings ST0 to ST5 may include at least one drain select transistor, a plurality of memory cells, at least one first up source select transistor, at least one second up source select transistor, at least one first down source select transistor, and at least one second down source select transistor.

The plurality of memory strings ST0 to ST5 may be configured to have a similar structure.

For example, the memory string ST0 may include a drain select transistor DST0, a plurality of memory cells MC00 to MC0n, second up source select transistors SST0_UP1, first up source select transistors SST0_UP0, second down source select transistors SST0_DN1, and first down source select transistors SST0_DN0 which are connected in series between the bit line BL and the common source line CSL. A gate of the drain select transistor DST0 may be electrically coupled to a drain select line DSL0, gates of the plurality of memory cells MC00 to MC0n may be electrically coupled to a plurality of word lines WLs (WL0 to WLn), gates of the second up source select transistors SST0_UP1 may be electrically coupled in common to one second up source select line SSL_UP<1>, gates of the first up source select transistors SST0_UP0 may be electrically coupled in common to one first up source select line SSL_UP<0>, gates of the second down source select transistors SST0_DN1 may be electrically coupled in common to one second down source select line SSL_DN<1>, and gates of the first down source select transistors SST0_DN0 may be electrically coupled in common to one first down source select line SSL_DN<0>.

Also, the memory string ST1 may include a drain select transistor DST1, a plurality of memory cells MC10 to MC1n, second up source select transistors SST1_UP1, first up source select transistors SST1_UP0, second down source select transistors SST1_DN1, and first down source select transistors SST1_DN0 which are connected in series between the bit line BL and the common source line CSL. A gate of the drain select transistor DST1 may be electrically coupled to a drain select line DSL1, gates of the plurality of memory cells MC10 to MCIn may be electrically coupled to a plurality of word lines WLs (WL0 to WLn), gates of the second up source select transistors SST1_UP1 may be electrically coupled in common to one second up source select line SSL_UP<1>, gates of the first up source select transistors SST1_UP0 may be electrically coupled in common to one first up source select line SSL_UP<0>, gates of the second down source select transistors SST1_DN1 may be electrically coupled in common to one second down source select line SSL_DN<1>, and gates of the first down source select transistors SST1_DN0 may be electrically coupled in common to one first down source select line SSL_DN<0>.

The memory string ST2 may include a drain select transistor DST2, a plurality of memory cells MC20 to MC2n, second up source select transistors SST2_UP1, first up source select transistors SST2_UP0, second down source select transistors SST2_DN1, and first down source select transistors SST2_DN0 which are connected in series between the bit line BL and the common source line CSL. A gate of the drain select transistor DST2 may be electrically coupled to a drain select line DSL2, gates of the plurality of memory cells MC20 to MC2n may be electrically coupled to a plurality of word lines WLs (WL0 to WLn), gates of the second up source select transistors SST2_UP1 may be electrically coupled in common to one second up source select line SSL_UP<1>, gates of the first up source select transistors SST2_UP0 may be electrically coupled in common to one first up source select line SSL_UP<0>, gates of the second down source select transistors SST2_DN1 may be electrically coupled in common to one second down source select line SSL_DN<1>, and gates of the first down source select transistors SST2_DN0 may be electrically coupled in common to one first down source select line SSL_DN<0>.

The memory string ST3 may include a drain select transistor DST3, a plurality of memory cells MC30 to MC3n, second up source select transistors SST3_UP1, first up source select transistors SST3_UP0, second down source select transistors SST3_DN1, and first down source select transistors SST3_DN0 which are connected in series between the bit line BL and the common source line CSL. A gate of the drain select transistor DST3 may be electrically coupled to a drain select line DSL3, gates of the plurality of memory cells MC30 to MC3n may be electrically coupled to a plurality of word lines WLs (WL0 to WLn), gates of the second up source select transistors SST3_UP1 may be electrically coupled in common to one second up source select line SSL_UP<1>, gates of the first up source select transistors SST3_UP0 may be electrically coupled in common to one first up source select line SSL_UP<0>, gates of the second down source select transistors SST3_DN1 may be electrically coupled in common to one second down source select line SSL_DN<1>, and gates of the first down source select transistors SST3_DN0 may be electrically coupled in common to one first down source select line SSL_DN<0>.

The memory string ST4 may include a drain select transistor DST4, a plurality of memory cells MC40 to MC4n, second up source select transistors SST4_UP1, first up source select transistors SST4_UP0, second down source select transistors SST4_DN1, and first down source select transistors SST4_DN0 which are connected in series between the bit line BL and the common source line CSL. A gate of the drain select transistor DST4 may be electrically coupled to a drain select line DSL4, gates of the plurality of memory cells MC40 to MC4n may be electrically coupled to a plurality of word lines WLs (WL0 to WLn), gates of the second up source select transistors SST4_UP1 may be electrically coupled in common to one second up source select line SSL_UP<1>, gates of the first up source select transistors SST4_UP0 may be electrically coupled in common to one first up source select line SSL_UP<0>, gates of the second down source select transistors SST4_DN1 may be electrically coupled in common to one second down source select line SSL_DN<1>, and gates of the first down source select transistors SST4_DN0 may be electrically coupled in common to one first down source select line SSL_DN<0>.

The memory string ST5 may include a drain select transistor DST5, a plurality of memory cells MC50 to MC5n, second up source select transistors SST5_UP1, first up source select transistors SST5_UP0, second down source select transistors SST5_DN1, and first down source select transistors SST5_DN0 which are connected in series between the bit line BL and the common source line CSL. A gate of the drain select transistor DST5 may be electrically coupled to a drain select line DSL5, gates of the plurality of memory cells MC50 to MC5n may be electrically coupled to a plurality of word lines WLs (WL0 to WLn), gates of the second up source select transistors SST5_UP1 may be electrically coupled in common to one second up source select line SSL_UP<1>, gates of the first up source select transistors SST5_UP0 may be electrically coupled in common to one first up source select line SSL_UP<0>, gates of the second down source select transistors SST5_DN1 may be electrically coupled in common to one second down source select line SSL_DN<1>, and gates of the first down source select transistors SST5_DN0 may be electrically coupled in common to one first down source select line SSL_DN<0>.

As described above, the plurality of memory strings ST0 to ST5 may be electrically coupled to different drain select lines DSL0 to DSL5, respectively. The plurality of memory strings ST0 to ST5 may be electrically coupled in common to the plurality of word lines WLs (WL0 to WLn), the second up source select line SSL_UP<1>, the first up source select line SSL_UP<0>, the second down source select line SSL_DN<1>, and the first down source select line SSL_DN<0>. For example, the memory string ST0 may be coupled to the drain select line DSL0 and the memory string ST1 may be coupled to the drain select line DSL1. For example, the plurality of memory strings ST0 to ST5 may be electrically coupled to the plurality of word lines WLs (WL0 to WLn), the second up source select line SSL_UP<1>, the first up source select line SSL_UP<0>, the second down source select line SSL_DN<1>, and the first down source select line SSL_DN<0> in common.

In an embodiment of the present disclosure, the plurality of memory strings ST0 to ST5 adjacent to each other may be defined as one string group. For example, the memory strings ST0, ST1, and ST2 may be defined as a first string group SG_A, and the memory strings ST3, ST4, and ST5 may be defined as a second string group SG_B.

Further, the second up source select transistors SST0_UP1, SST1_UP1, and SST2_UP1 of the first string group SG_A may be defined as a first coding group GA, the second up source select transistors SST3_UP1, SST4_UP1, and SST5_UP1 of the second string group SG_B may be defined as a second coding group GB, the first up source select transistors SST0_UP0, SST1_UP0, and SST2_UP0 of the first string group SG_A may be defined as a third coding group GC, and the first up source select transistors SST3_UP0, SST4_UP0, and SST5_UP0 of the second string group SG_B may be defined as a fourth coding group GD.

The second up source select transistors SST0_UP1, SST1_UP1, and SST2_UP1 of the first coding group GA and the second up source select transistors SST3_UP1, SST4_UP1, and SST5_UP1 of the second coding group GB may be programmed to different states. For example, the second up source select transistors SST0_UP1, SST1_UP1, and SST2_UP1 of the first coding group GA may be programmed to a first state corresponding to data “1”, and the second up source select transistors SST3_UP1, SST4_UP1, and SST5_UP1 of the second coding group GB may be programmed to a second state corresponding to data “0”. For example, the first state may be that data “1” may be programed in one of the source select transistors and the second state may be that data “0” may be programed in one of the source select transistors. As above described, the data “1” may be defined as an erase state in which a threshold voltage is lower than a set voltage level (e.g., read voltage level), and the data “0” may be defined as a program state in which the threshold voltage is equal to or higher than the set level.

The first up source select transistors SST0_UP0, SST1_UP0, and SST2_UP0 of the third coding group GC and the first up source select transistors SST3_UP0, SST4_UP0, and SST5_UP0 included in the fourth coding group GD may be programmed to different states. For example, the first up source select transistors SST0_UP0, SST1_UP0, and SST2_UP0 included in the third coding group GC may be programmed to a second state corresponding to data “0”, and the first up source select transistors SST3_UP0, SST4_UP0, and SST5_UP0 included in the fourth coding group GD may be programmed to a first state corresponding to data “1”.

Accordingly, a coding data value of the second up source select transistors SST0_UP1 to SST2_UP1 (e.g., the first coding group: GA) and the first up source select transistors SST0_UP0 to SST2_UP0 (e.g., the third coding group: GC) of the memory strings ST0, ST1, and ST2 of the first string group SG_A may have a value of “10”. A coding data value of the second up source select transistors SST3_UP1 to SST5_UP1 (e.g., the second coding group: GB) and the first up source select transistors SST3_UP0 to SST5_UP0 (e.g., the fourth coding group: GD) of the memory strings ST3, ST4, and ST5 included in the second string group SG_B may have a value of “01”. That is, the second up source select transistors and the first up source select transistors may be programmed such that respective string groups have different coding data values.

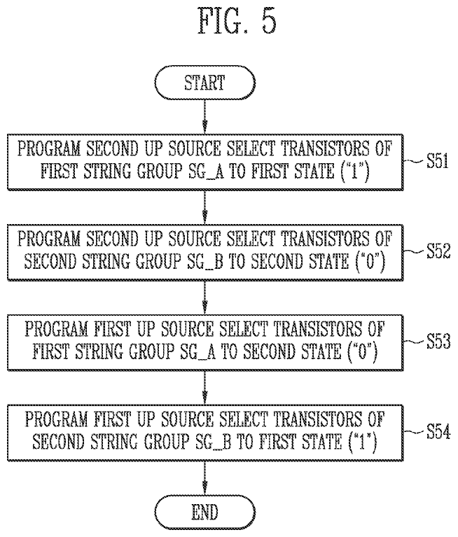

FIG. 5 is a flowchart for explaining a program operation on source select transistors according to an embodiment of the present disclosure.

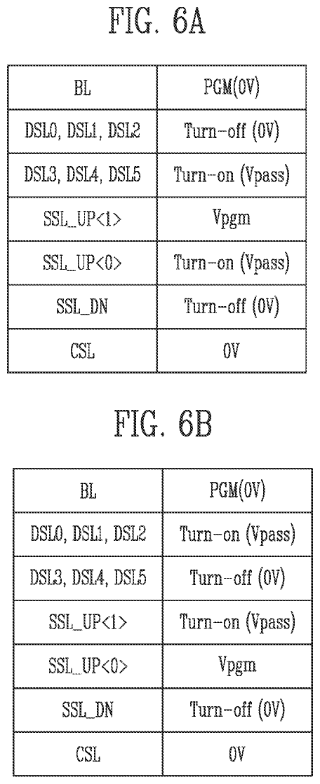

FIGS. 6A and 6B are diagrams for explaining voltages applied during a program operation on source select transistors according to an embodiment of the present disclosure.

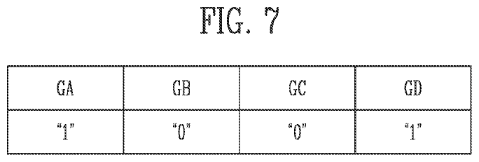

FIG. 7 is a diagram for explaining the states of a plurality of source select transistor groups after the program operation is performed on the source select transistors.

In this embodiment, a program operation performed on the source select transistors of the memory block illustrated in FIG. 3 or the memory block illustrated in FIG. 4 will be described with reference to FIGS. 1 to 5, 6A, 6B, and 7.

At step S51, the second up source select transistors SST0_UP1, SST1_UP1, and SST2_UP1 of the first string group SG_A may be programmed to a first state corresponding to data “1”.

At step S52, the second up source select transistors SST3_UP1, SST4_UP1, and SST5_UP1 of the second string group SG_B may be programmed to a second state corresponding to data “0” which is different from the first state.

The program operations on the second up source select transistors SST0_UP1, SST1_UP1, SST2_UP1, SST3_UP1, SST4_UP1, and SST5_UP1 at the steps S51 and S52 may be performed together. In an embodiment, the program operations on the second up source select transistors SST0_UP1, SST1_UP1, SST2_UP1, SST3_UP1, SST4_UP1, and SST5_UP1 at the steps S51 and S52 may be performed simultaneously. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

For example, the plurality of page buffers PB1 to PBm of the read and write circuit 130 may apply a program-enable voltage PGM to the bit lines BL1 to BLm. For example, the program-enable voltage PGM may be 0 V.

The address decoder 120 may receive the operating voltages Vpgm, Vread and Vpass generated by the voltage generator 150 and address signal (not shown) for selecting a memory cell of a memory string. Further, the address decoder 120 may apply the operating voltages Vpgm, Vread and Vpass to the drain select lines DSL0 to DSL5, the plurality of word lines WLs, the first up source select line SSL_UP<0>, the second up source line SSL_UP<1>, and the down source select line SSL_DN of a selected memory block (e.g., BLK1) based on the address as shown in FIG. 1.

For example, as illustrated in FIG. 6A, a turn-off voltage of 0 V may be applied to the gates of the drain select lines DSL0, DSL1, and DSL2 of the first string group SG_A, and a turn-on voltage, that is, the pass voltage Vpass, may be applied to the gates of the drain select lines DSL3, DSL4, and DSL5 of the second string group SG_B. Further, the turn-off voltage of 0 V may be applied to the down source select line SSL_DN. Accordingly, the channels of the memory strings ST0, ST1, and ST2 of the first string group SG_A may be controlled to float, and the program-enable voltage PGM may be applied to the channels of the memory strings ST3, ST4, and ST5 of the second string group SG_B, and then the channels may be controlled to a potential of 0 V corresponding to the program-enable voltage PGM. Thereafter, the program voltage Vpgm may be applied to the second up source select line SSL_UP<1> coupled to the second up source select transistors SST0_UP1, SST1_UP1, SST2_UP1, SST3_UP1, SST4_UP1, and SST5_UP1, and the turn-on voltage, that is, the pass voltage Vpass, may be applied to the first up source select line SSL_UP<0> and the word lines WLs. Accordingly, the second up source select transistors SST0_UP1, SST1_UP1, and SST2_UP1 of the first coding group GA of the first string group SG_A may be programmed to have the first state that is an erase state corresponding to data “1”, because the channels of the second up source select transistors SST0_UP1, SST1_UP1, and SST2_UP1 of the first coding group GA may be floated. For example, when the channels of the second up source select transistors SST0_UP1, SST1_UP1, and SST2_UP1 may be floated and the gates of the second up source select transistors SST0_UP1, SST1_UP1, and SST2_UP1 may receive the program voltage including a negative voltage level, charges in the memory layers of the second up source select transistors SST0_UP1, SST1_UP1, and SST2_UP1 flow into the channels, to program the second up source select transistors SST0_UP1, SST1_UP1, and SST2_UP1 to data “1”.

Further, the second up source select transistors SST3_UP1, SST4_UP1, and SST5_UP1 of the second coding group GB of the second string group SG_B, may be programmed to have the second state that is a program state corresponding to data “0”, because the channels of the second up source select transistors SST3_UP1, SST4_UP1, and SST5_UP1 of the second coding group GB may include the level of the program-enable voltage PGM that is, OV. For example, when the channels of the second up source select transistors SST3_UP1, SST4_UP1, and SST5_UP1 may keep OV and the gates of the second up source select transistors SST3_UP1, SST4_UP1, and SST5_UP1 may receive the program voltage including a negative voltage level, charges in the channels and body portions of the second up source select transistors SST0_UP1, SST1_UP1, and SST2_UP1 collect ow into the memory layers, to program the second up source select transistors SST3_UP1, SST4_UP1, and SST5_UP1 to data “0”.

At step S53, the first up source select transistors SST0_UP0, SST1_UP0, and SST2_UP0 of the first string group SG_A may be programmed to the second state for programing the data “0”.

At step S54, the first up source select transistors SST3_UP0, SST4_UP0, and SST5_UP0 of the second string group SG_B may be programmed to the first state for programing the data “1”.

The program operations on the first up source select transistors SST0_UP0, SST1_UP0, SST2_UP0, SST3_UP0, SST4_UP0, and SST5_UP0 at the steps S53 and S54 may be performed together.

Similarly to the steps 51 and 52, the plurality of page buffers PB1 to PBm of the read and write circuit 130 may apply the program-enable voltage PGM (e.g., OV) to the bit lines BL1 to BLm.

The address decoder 120 may apply the operating voltages Vpgm, Vread and Vpass to the drain select lines DSL0 to DSL5, the plurality of word lines WLs, the first up source select line SSL_UP<0>, the second up source line SSL_UP<1>, and the down source select line SSL_DN of a selected memory block (e.g., BLK1).

For example, as illustrated in FIG. 6B, the turn-on voltage, that is, the pass voltage Vpass, may be applied to the gates of the drain select lines DSL0, DSL1, and DSL2 of the first string group SG_A, and the turn-off voltage of 0 V may be applied to the gates of the drain select lines DSL3, DSL4, and DSL5 of the second string group SG_B. Further, the turn-off voltage of 0 V may be applied to the down source select line SSL_DN. Accordingly, the program-enable voltage PGM may be applied to the channels of the memory strings ST0, ST1, and ST2 of the first string group SG_A, and then the channels may be controlled to a potential of 0 V. The channels of the memory strings ST3, ST4, and ST5 of the second string group SG_B may be controlled to float. Thereafter, the program voltage Vpgm may be applied to the first up source select line SSL_UP<0> coupled to the first up source select transistors SST0_UP0, SST1_UP0, SST2_UP0, SST3_UP0, SST4_UP0, and SST5_UP0, and the turn-on voltage, that is, the pass voltage Vpass, may be applied to the second up source select line SSL_UP<1> and the word lines WLs. Accordingly, the first up source select transistors SST3_UP0, SST4_UP0, and SST5_UP0 of the fourth coding group GD of the second string group SG_B may be programmed to have the first state that is the erase state corresponding to data “1”, because the channels of the first up source select transistors SST3_UP0, SST4_UP0, and SST5_UP0 may be controlled to float. Further, the first up source select transistors SST0_UP0, SST1_UP0, and SST2_UP0 of the third coding group GC included in the first string group SG_A may be programmed to have the second state that is the program state corresponding to data “0”, the channels of the first up source select transistors SST0_UP0, SST1_UP0, and SST2_UP0 may be controlled to the level of the program-enable voltage PGM.

Thus, the coding data value of the second up source select transistors and the first up source select transistors of the memory strings ST0, ST1, and ST2 included in the first string group SG_A may have a value of “10”, and the coding data value of the second up source select transistors and the first up source select transistors of the memory strings ST3, ST4, and ST5 included in the second string group SG_B may have a value of “01”. That is, the second up source select transistors and the first up source select transistors may be programmed such that respective string groups have different coding data values.

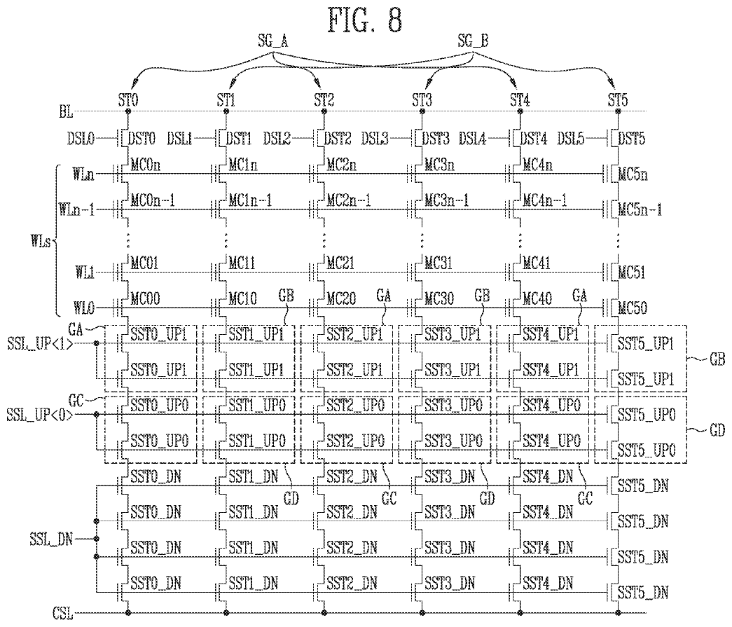

FIG. 8 is a circuit diagram for explaining a memory block according to an embodiment of the present disclosure.

Referring to FIG. 8, the memory block may include a plurality of memory strings ST0 to ST5 connected in parallel between one bit line BL and a common source line CSL.

Each of the plurality of memory strings ST0 to ST5 may include at least one drain select transistor, a plurality of memory cells, at least one first up source select transistor, at least one second up source select transistor, and at least one down source select transistor. For example, the first up source select transistor and the second up source select transistor may include a transistor with a memory layer as the memory cell.

The plurality of memory strings ST0 to ST5 may be configured to have a similar structure.

For example, the memory string ST0 may include a drain select transistor DST0, a plurality of memory cells MC00 to MC0n, second up source select transistors SST0_UP1, first up source select transistors SST0_UP0, and down source select transistors SST0_DN which are connected in series between the bit line BL and the common source line CSL. A gate of the drain select transistor DST0 may be electrically coupled to a drain select line DSL0, gates of the plurality of memory cells MC00 to MC0n may be electrically coupled to a plurality of word lines WLs (WL0 to WLn), gates of the second up source select transistors SST0_UP1 may be electrically coupled in common to one second up source select line SSL_UP<1>, gates of the first up source select transistors SST0_UP0 may be electrically coupled in common to one first up source select line SSL_UP<0>, and gates of the down source select transistors SST0_DN may be electrically coupled to one down source select line SSL_DN.

Also, the memory string ST1 may include a drain select transistor DST1, a plurality of memory cells MC10 to MC1n, second up source select transistors SST1_UP1, first up source select transistors SST1_UP0, and down source select transistors SST1_DN which are connected in series between the bit line BL and the common source line CSL. For example, the plurality of memory cells MC10 to MC1n, second up source select transistors SST1_UP1, first up source select transistors SST1_UP0 may include a transistor with a memory layer. A gate of the drain select transistor DST1 may be electrically coupled to a drain select line DSL1, gates of the plurality of memory cells MC10 to MCIn may be electrically coupled to the plurality of word lines WLs (WL0 to WLn), gates of the second up source select transistors SST1_UP1 may be electrically coupled in common to the one second up source select line SSL_UP<1>, gates of the first up source select transistors SST1_UP0 may be electrically coupled in common to the one first up source select line SSL_UP<0>, and gates of the down source select transistors SST1_DN may be electrically coupled to the one down source select line SSL_DN.

The memory string ST2 may include a drain select transistor DST2, a plurality of memory cells MC20 to MC2n, second up source select transistors SST2_UP1, first up source select transistors SST2_UP0, and down source select transistors SST2_DN which are connected in series between the bit line BL and the common source line CSL. A gate of the drain select transistor DST2 may be electrically coupled to a drain select line DSL2, gates of the plurality of memory cells MC20 to MC2n may be electrically coupled to the plurality of word lines WLs (WL0 to WLn), gates of the second up source select transistors SST2_UP1 may be electrically coupled in common to the one second up source select line SSL_UP<1>, gates of the first up source select transistors SST2_UP0 may be electrically coupled in common to the one first up source select line SSL_UP<0>, and gates of the down source select transistors SST2_DN may be electrically coupled to the one down source select line SSL_DN.

The memory string ST3 may include a drain select transistor DST3, a plurality of memory cells MC30 to MC3n, second up source select transistors SST3_UP1, first up source select transistors SST3_UP0, and down source select transistors SST3_DN which are connected in series between the bit line BL and the common source line CSL. A gate of the drain select transistor DST3 may be electrically coupled to a drain select line DSL3, gates of the plurality of memory cells MC30 to MC3n may be electrically coupled to a plurality of word lines WLs (WL0 to WLn), gates of the second up source select transistors SST3_UP1 may be electrically coupled in common to one second up source select line SSL_UP<1>, gates of the first up source select transistors SST3_UP0 may be electrically coupled in common to one first up source select line SSL_UP<0>, and gates of the down source select transistors SST3_DN may be electrically coupled to one down source select line SSL_DN.

The memory string ST4 may include a drain select transistor DST4, a plurality of memory cells MC40 to MC4n, second up source select transistors SST4_UP1, first up source select transistors SST4_UP0, and down source select transistors SST4_DN which are connected in series between the bit line BL and the common source line CSL. A gate of the drain select transistor DST4 may be electrically coupled to a drain select line DSL4, gates of the plurality of memory cells MC40 to MC4n may be electrically coupled to a plurality of word lines WLs (WL0 to WLn), gates of the second up source select transistors SST4_UP1 may be electrically coupled in common to one second up source select line SSL_UP<1>, gates of the first up source select transistors SST4_UP0 may be electrically coupled in common to one first up source select line SSL_UP<0>, and gates of the down source select transistors SST4_DN may be electrically coupled to one down source select line SSL_DN.

The memory string ST5 may include a drain select transistor DST5, a plurality of memory cells MC50 to MC5n, second up source select transistors SST5_UP1, first up source select transistors SST5_UP0, and down source select transistors SST5_DN which are connected in series between the bit line BL and the common source line CSL. A gate of the drain select transistor DST5 may be electrically coupled to a drain select line DSL5, gates of the plurality of memory cells MC50 to MC5n may be electrically coupled to a plurality of word lines WLs (WL0 to WLn), gates of the second up source select transistors SST5_UP1 may be electrically coupled in common to one second up source select line SSL_UP<1>, gates of the first up source select transistors SST5_UP0 may be electrically coupled in common to one first up source select line SSL_UP<0>, and gates of the down source select transistors SST5_DN may be electrically coupled to one down source select line SSL_DN.

As described above, the plurality of memory strings ST0 to ST5 may be electrically coupled to different drain select lines DSL0 to DSL5, respectively, and may be electrically coupled in common to the plurality of word lines WLs (WL0 to WLn), the second up source select line SSL_UP<1>, the first up source select line SSL_UP<0>, and the down source select line SSL_DN. That is, the plurality of memory strings ST0 to ST5 may correspond to different drain select lines DSL0 to DSL5, respectively, and may share the plurality of word lines WLs (WL0 to WLn), the second up source select line SSL_UP<1>, the first up source select line SSL_UP<0>, and the down source select line SSL_DN.

In an embodiment of the present disclosure, even memory strings ST0, ST2, and ST4 among the plurality of memory strings ST0 to ST5 may be defined as a first string group SG_A, and odd memory strings ST1, ST3, and ST5 among the plurality of memory strings ST0 to ST5 may be defined as a second string group SG_B. Accordingly, the first string group SG_A and the second string group SG_B may be alternately arranged.

Further, the second up source select transistors SST0_UP1, SST2_UP1, and SST4_UP1 included in the first string group SG_A may be defined as a first coding group GA, the second up source select transistors SST1_UP1, SST3_UP1, and SST5_UP1 included in the second string group SG_B may be defined as a second coding group GB, the first up source select transistors SST0_UP0, SST2_UP0, and SST4_UP0 included in the first string group SG_A may be defined as a third coding group GC, and the first up source select transistors SST1_UP0, SST3_UP0, and SST5_UP0 included in the second string group SG_B may be defined as a fourth coding group GD.

The second up source select transistors SST0_UP1, SST2_UP1, and SST4_UP1 of the first coding group GA and the second up source select transistors SST1_UP1, SST3_UP1, and SST5_UP1 of the second coding group GB may be programmed to different states. For example, the second up source select transistors SST0_UP1, SST2_UP1, and SST4_UP1 of the first coding group GA may be programmed to a first state corresponding to data “1”, and the second up source select transistors SST1_UP1, SST3_UP1, and SST5_UP1 of the second coding group GB may be programmed to a second state corresponding to data “0”. For example, the first state corresponding to data “1” may be defined as an erase state in which a threshold voltage is lower than a set level (e.g., read voltage level), and the second state corresponding to data “0” may be defined as a program state in which the threshold voltage is equal to or higher than the set level.

The first up source select transistors SST0_UP0, SST2_UP0, and SST4_UP0 of the above-described third coding group GC and the first up source select transistors SST1_UP0, SST3_UP0, and SST5_UP0 of the fourth coding group GD may be programmed to different states. The first up source select transistors SST0_UP0, SST2_UP0, and SST4_UP0 of the third coding group GC may be programmed to the second state corresponding to data “0”, and the first up source select transistors SST1_UP0, SST3_UP0, and SST5_UP0 of the fourth coding group GD may be programmed to the first state corresponding to data “1”.

Accordingly, the coding data value of the second up source select transistors and the first up source select transistors of the memory strings ST0, ST2, and ST4 included in the first string group SG_A may have a value of “10”, and the coding data value of the second up source select transistors and the first up source select transistors of the memory strings ST1, ST3, and ST5 included in the second string group SG_B may have a value of “01”. That is, the second up source select transistors and the first up source select transistors may be programmed such that respective string groups have different coding data values. Furthermore, in respective memory strings adjacent to each other, the second up source select transistors and the first up source select transistors may be programmed to different program states.

As described above, although the first up source select transistors SST0_UP0, SST1_UP0, and SST2_UP0 of the first string group SG_A, and the first up source select transistors SST3_UP0, SST4_UP0, and SST5_UP0 of the second string group SG_B may be programed (or controlled) based on the first up source select line SSL_UP<0> in common. The second up source select transistors SST0_UP1, SST1_UP1, and SST2_UP1 of the first string group SG_A, and the second up source select transistors SST3_UP1, SST4_UP1, and SST5_UP1 of the second string group SG_B may be programed (or controlled) based on the second up source select line SSL_UP<1> in common. That is, the second up source select transistors and the first up source select transistors may be programmed such that memory strings adjacent to each other have different coding data values. As a result, one string group may be selectively activated by controlling signals applied to the first up source select line SSL_UP<0> and the second up source select line SSL_UP<1> during a read operation.

The method of programming the above-described first coding group GA to fourth coding group GD of FIG. 8 may be performed based on the method of programming the source select transistors, described above with reference to FIGS. 1, 5, 6A, 6B, and 7.

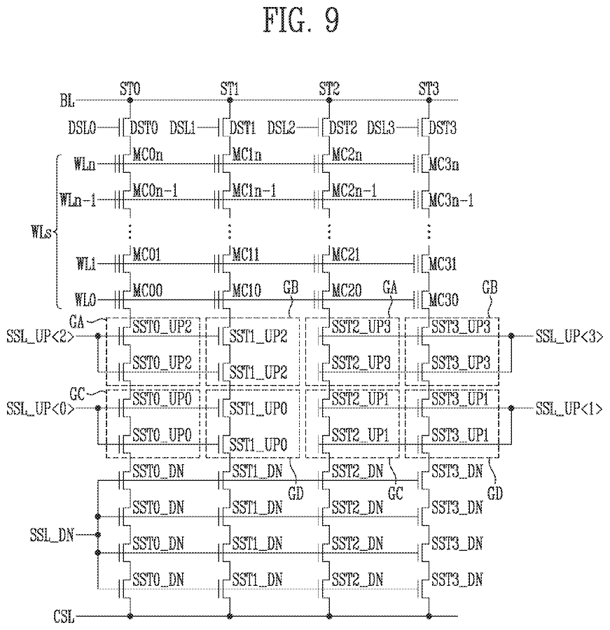

FIG. 9 is a circuit diagram for explaining a memory block according to an embodiment of the present disclosure.

Referring to FIG. 9, the memory block may include a plurality of memory strings ST0 to ST3 connected in parallel between one bit line BL and a common source line CSL.

Each of the plurality of memory strings ST0 to ST3 may include at least one drain select transistor, a plurality of memory cells, at least one first up source select transistor, at least one second up source select transistor, and at least one down source select transistor.

The plurality of memory strings ST0 to ST3 may be configured to have a similar structure.

For example, the memory string ST0 may include a drain select transistor DST0, a plurality of memory cells MC00 to MC0n, second up source select transistors SST0_UP2, first up source select transistors SST0_UP0, and down source select transistors SST0_DN which are connected in series between the bit line BL and the common source line CSL. A gate of the drain select transistor DST0 may be electrically coupled to a drain select line DSL0, gates of the plurality of memory cells MC00 to MC0n may be electrically coupled to a plurality of word lines WLs (WL0 to WLn), gates of the second up source select transistors SST0_UP2 may be electrically coupled in common to one second up source select line SSL_UP<2>, gates of the first up source select transistors SST0_UP0 may be electrically coupled in common to one first up source select line SSL_UP<0>, and gates of the down source select transistors SST0_DN may be electrically coupled to one down source select line SSL_DN.

Also, the memory string ST1 may include a drain select transistor DST1, a plurality of memory cells MC10 to MC1n, second up source select transistors SST1_UP2, first up source select transistors SST1_UP0, and down source select transistors SST1_DN which are connected in series between the bit line BL and the common source line CSL. A gate of the drain select transistor DST1 may be electrically coupled to a drain select line DSL1, gates of the plurality of memory cells MC10 to MC1n may be electrically coupled to the plurality of word lines WLs (WL0 to WLn), gates of the second up source select transistors SST1_UP2 may be electrically coupled in common to the one second up source select line SSL_UP<2>, gates of the first up source select transistors SST1_UP0 may be electrically coupled in common to the one first up source select line SSL_UP<0>, and gates of the down source select transistors SST1_DN may be electrically coupled to the one down source select line SSL_DN.

The memory string ST2 may include a drain select transistor DST2, a plurality of memory cells MC20 to MC2n, second up source select transistors SST2_UP3, first up source select transistors SST2_UP1, and down source select transistors SST2_DN which are connected in series between the bit line BL and the common source line CSL. A gate of the drain select transistor DST2 may be electrically coupled to a drain select line DSL2, gates of the plurality of memory cells MC20 to MC2n may be electrically coupled to a plurality of word lines WLs (WL0 to WLn), gates of the second up source select transistors SST2_UP3 may be electrically coupled in common to one second up source select line SSL_UP<3>, gates of the first up source select transistors SST2_UP1 may be electrically coupled in common to one first up source select line SSL_UP<1>, and gates of the down source select transistors SST2_DN may be electrically coupled to one down source select line SSL_DN.

The memory string ST3 may include a drain select transistor DST3, a plurality of memory cells MC30 to MC3n, second up source select transistors SST3_UP3, first up source select transistors SST3_UP1, and down source select transistors SST3_DN which are connected in series between the bit line BL and the common source line CSL. A gate of the drain select transistor DST3 may be electrically coupled to a drain select line DSL3, gates of the plurality of memory cells MC30 to MC3n may be electrically coupled to a plurality of word lines WLs (WL0 to WLn), gates of the second up source select transistors SST3_UP3 may be electrically coupled in common to one second up source select line SSL_UP<3>, gates of the first up source select transistors SST3_UP1 may be electrically coupled in common to one first up source select line SSL_UP<1>, and gates of the down source select transistors SST3_DN may be electrically coupled to one down source select line SSL_DN.

As described above, the plurality of memory strings ST0 to ST3 may be electrically coupled to different drain select lines DSL0 to DSL3, respectively, and may be electrically coupled in common to the plurality of word lines WLs (WL0 to WLn), and the down source select lien SSL_DN. Furthermore, the memory strings ST0 and ST1 adjacent to each other may be electrically coupled in common to the second up source select line SSL_UP<2> and the first up source select line SSL_UP<0>, and the memory strings ST2 and ST3 adjacent to each other may be electrically coupled in common to the second up source select line SSL_UP<3> and the first up source select line SSL_UP<1>.

That is, the plurality of memory strings ST0 to ST3 may correspond to different drain select lines DSL0 to DSL3, respectively, and may share the plurality of word lines WLs (WL0 to WLn) and the down source select line SSL_DN, but respective string groups, including memory strings adjacent to each other, may correspond to different first and second up source select lines.

In an embodiment of the present disclosure, the plurality of memory strings adjacent to each other may be defined as one string group. For example, the memory strings ST0 and ST1 may be defined as a first string group, and the memory strings ST2 and ST3 may be defined as a second string group.

In an embodiment of the present disclosure, the second up source select transistors of the plurality of memory strings which share one second up source select line with each other may be divided into different coding groups. For example, the second up source select transistors SST0_UP2 of the memory string ST0 controlled by the second up source select line SSL_UP<2> may be defined as a first coding group GA, and the second up source select transistors SST1_UP2 of the memory string ST1 controlled by the second up source select line SSL_UP<2> may be defined as a second coding group GB. Also, the second up source select transistors SST2_UP3 of the memory string ST2 sharing the second up source select line SSL_UP<3> may be defined as a first coding group GA, and the second up source select transistors SST2_UP3 of the memory string ST3 sharing the second up source select line SSL_UP<3> may be defined as a second coding group GB. The first up source select transistors respectively included in a plurality of memory strings which share one first up source select line with each other may be divided into different coding groups. For example, the first up source select transistors SST0_UP0 of the memory string ST0 sharing the first up source select line SSL_UP<0> may be defined as a third coding group GC, and the first up source select transistors SST1_UP0 of the memory string ST1 sharing the first up source select line SSL_UP<0> may be defined as a fourth coding group GD. Further, the second up source select transistors SST2_UP1 of the memory string ST2 sharing the first up source select line SSL_UP<1> may be defined as a third coding group GC, and the first up source select transistors SST3_UP1 of the memory string ST3 sharing the first up source select line SSL_UP<1> may be defined as a fourth coding group GD.

The second up source select transistors SST0_UP2 and SST2_UP3 included in the above-described first coding group GA and the second up source select transistors SST1_UP2 and SST3_UP3 included in the second coding group GB may be programmed to different states. For example, the second up source select transistors SST0_UP2 and SST2_UP3 included in the first coding group GA may be programmed to a first state corresponding to data “1”, and the second up source select transistors SST1_UP2 and SST3_UP3 included in the second coding group GB may be programmed to a second state corresponding to data “0”. For example, the first state corresponding to data “1” may be defined as an erase state in which a threshold voltage is lower than a set level, and the second state corresponding to data “0” may be defined as a program state in which the threshold voltage is equal to or higher than the set level.

The first up source select transistors SST0_UP0 and SST2_UP1 included in the above-described third coding group GC and the first up source select transistors SST1_UP0 and SST3_UP1 included in the fourth coding group GD may be programmed to different states. The first up source select transistors SST0_UP0 and SST2_UP1 included in the third coding group GC may be programmed to the second state corresponding to data “0”, and the first up source select transistors SST1_UP0 and SST3_UP1 included in the fourth coding group GD may be programmed to the first state corresponding to data “1”.

Accordingly, the coding data value of the second up source select transistors and the first up source select transistors of the memory strings ST0 and ST2 may have a value of “10”, and the coding data value of the second up source select transistors and the first up source select transistors of the memory strings ST1 and ST3 may have a value of “01”. That is, the memory strings which share the second up source select line and the first up source select line may program the second up source select transistors and the first up source select transistors to have different coding data values.

The method of programming the above-described first coding group GA to fourth coding group GD of FIG. 9 may be performed based on the method of programming the source select transistors, described above with reference to FIGS. 1, 5, 6A, 6B, and 7.

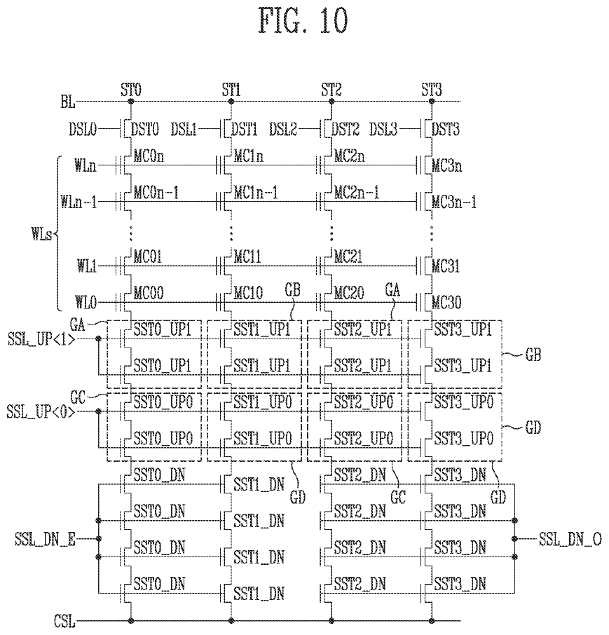

FIG. 10 is a circuit diagram for explaining a memory block according to an embodiment of the present disclosure.

Referring to FIG. 10, the memory block may include a plurality of memory strings ST0 to ST3 connected in parallel between one bit line BL and a common source line CSL.

Each of the plurality of memory strings ST0 to ST3 may include at least one drain select transistor, a plurality of memory cells, at least one first up source select transistor, at least one second up source select transistor, and at least one down source select transistor.

The plurality of memory strings ST0 to ST3 may be configured to have a similar structure.

For example, the memory string ST0 may include a drain select transistor DST0, a plurality of memory cells MC00 to MC0n, second up source select transistors SST0_UP1, first up source select transistors SST0_UP0, and down source select transistors SST0_DN which are connected in series between the bit line BL and the common source line CSL. A gate of the drain select transistor DST0 may be electrically coupled to a drain select line DSL0, gates of the plurality of memory cells MC00 to MC0n may be electrically coupled to a plurality of word lines WLs (WL0 to WLn), gates of the second up source select transistors SST0_UP1 may be electrically coupled in common to one second up source select line SSL_UP<1>, gates of the first up source select transistors SST0_UP0 may be electrically coupled in common to one first up source select line SSL_UP<0>, and gates of the down source select transistors SST0_DN may be electrically coupled to one even down source select line SSL_DN_E.

Also, the memory string ST1 may include a drain select transistor DST1, a plurality of memory cells MC10 to MC1n, second up source select transistors SST1_UP1, first up source select transistors SST1_UP0, and down source select transistors SST1_DN which are connected in series between the bit line BL and the common source line CSL. A gate of the drain select transistor DST1 may be electrically coupled to a drain select line DSL1, gates of the plurality of memory cells MC10 to MCIn may be electrically coupled to the plurality of word lines WLs (WL0 to WLn), gates of the second up source select transistors SST1_UP1 may be electrically coupled in common to the one second up source select line SSL_UP<1>, gates of the first up source select transistors SST1_UP0 may be electrically coupled in common to the one first up source select line SSL_UP<0>, and gates of the down source select transistors SST1_DN may be electrically coupled to the one even down source select line SSL_DN_E.

The memory string ST2 may include a drain select transistor DST2, a plurality of memory cells MC20 to MC2n, second up source select transistors SST2_UP1, first up source select transistors SST2_UP0, and down source select transistors SST2_DN which are connected in series between the bit line BL and the common source line CSL. A gate of the drain select transistor DST2 may be electrically coupled to a drain select line DSL2, gates of the plurality of memory cells MC20 to MC2n may be electrically coupled to the plurality of word lines WLs (WL0 to WLn), gates of the second up source select transistors SST2_UP1 may be electrically coupled in common to the one second up source select line SSL_UP<1>, gates of the first up source select transistors SST2_UP0 may be electrically coupled in common to the one first up source select line SSL_UP<0>, and gates of the down source select transistors SST2_DN may be electrically coupled to one odd down source select line SSL_DN_O.

The memory string ST3 may include a drain select transistor DST3, a plurality of memory cells MC30 to MC3n, second up source select transistors SST3_UP1, first up source select transistors SST3_UP0, and down source select transistors SST3_DN which are connected in series between the bit line BL and the common source line CSL. A gate of the drain select transistor DST3 may be electrically coupled to a drain select line DSL3, gates of the plurality of memory cells MC30 to MC3n may be electrically coupled to a plurality of word lines WLs (WL0 to WLn), gates of the second up source select transistors SST3_UP1 may be electrically coupled in common to one second up source select line SSL_UP<1>, gates of the first up source select transistors SST3_UP0 may be electrically coupled in common to one first up source select line SSL_UP<0>, and gates of the down source select transistors SST3_DN may be electrically coupled to the one odd down source select line SSL_DN_O.

As described above, the plurality of memory strings ST0 to ST3 may be electrically coupled to different drain select lines DSL0 to DSL3, respectively, and may be electrically coupled in common to the plurality of word lines WLs (WL0 to WLn), the second up source select line SSL_UP<1>, and the first up source select line SSL_UP<0>. Also, among the plurality of memory strings ST0 to ST3, some memory strings ST0 and ST1 may be electrically coupled to the even down source select line SSL_DN_E, and the remaining memory strings ST2 and ST3 may be electrically coupled to the odd down source select line SSL_DN_O.

That is, the plurality of memory strings ST0 to ST3 may correspond to different drain select lines DSL0 to DSL3, respectively, and may share the plurality of word lines WLs (WL0 to WLn), the second up source select line SSL_UP<1>, and the first up source select line SSL_UP<0>, some memory strings ST0 and ST1 may share one even down source select line SSL_DN_E, and the remaining memory strings ST2 and ST3 may share one odd down source select line SSL_DN_O.

In an embodiment of the present disclosure, the plurality of memory strings adjacent to each other may be defined as one string group. For example, the memory strings ST0 and ST1 may be defined as a first string group, and the memory strings ST2 and ST3 may be defined as a second string group.

In an embodiment of the present disclosure, second up source select transistors and first up source select transistors respectively included in a plurality of memory strings which share one even down source select line SSL_DN_E or one odd down source select line SSL_DN_O may be divided into different coding groups.

For example, the second up source select transistors SST0_UP1 of the memory string ST0, of the memory strings ST0 and ST1 sharing the even down source select line SSL_DN_E, may be defined as a first coding group GA, and the second up source select transistors SST1_UP1 of the memory string ST1 may be defined as a second coding group GB. Also, the first up source select transistors SST0_UP0 of the memory string ST0, of the memory strings ST0 and ST1 sharing the even down source select line SSL_DN_E, may be defined as a third coding group GC, and the first up source select transistors SST1_UP0 of the memory string ST1 may be defined as a fourth coding group GD.

Further, the second up source select transistors SST2_UP1 of the memory string ST2, of the memory strings ST2 and ST3 sharing the odd down source select line SSL_DN_O, may be defined as a first coding group GA, and the second up source select transistors SST3_UP1 of the memory string ST3 may be defined as a second coding group GB. Further, the first up source select transistors SST2_UP0 of the memory string ST2, of the memory strings ST2 and ST3 sharing the odd down source select line SSL_DN_O, may be defined as a third coding group GC, and the first up source select transistors SST3_UP0 of the memory string ST3 may be defined as a fourth coding group GD.

The second up source select transistors SST0_UP1 and SST2_UP1 included in the first coding group GA and the second up source select transistors SST1_UP1 and SST3_UP1 included in the second coding group GB may be programmed to different states. For example, the second up source select transistors SST0_UP1 and SST2_UP1 included in the first coding group GA may be programmed to a first state corresponding to data “1”, and the second up source select transistors SST1_UP1 and SST3_UP1 included in the second coding group GB may be programmed to a second state corresponding to data “0”. For example, the first state corresponding to data “1” may be defined as an erase state in which a threshold voltage is lower than a set level, and the second state corresponding to data “0” may be defined as a program state in which the threshold voltage is equal to or higher than the set level.

The first up source select transistors SST0_UP0 and SST2_UP0 included in the above-described third coding group GC and the first up source select transistors SST1_UP0 and SST3_UP0 included in the fourth coding group GD may be programmed to different states. The first up source select transistors SST0_UP0 and SST2_UP0 included in the third coding group GC may be programmed to the second state corresponding to data “0”, and the first up source select transistors SST1_UP0 and SST3_UP0 included in the fourth coding group GD may be programmed to the first state corresponding to data “1”.

Accordingly, the coding data value of the second up source select transistors and the first up source select transistors of the memory strings ST0 and ST2 may have a value of “10”, and the coding data value of the second up source select transistors and the first up source select transistors of the memory strings ST1 and ST3 may have a value of “01”. That is, the memory strings which share the second up source select line and the first up source select line may program the second up source select transistors and the first up source select transistors to have different coding data values.

The method of programming the above-described first coding group GA to fourth coding group GD of FIG. 10 may be performed based on the method of programming the source select transistors, described above with reference to FIGS. 1, 5, 6A, 6B, and 7.

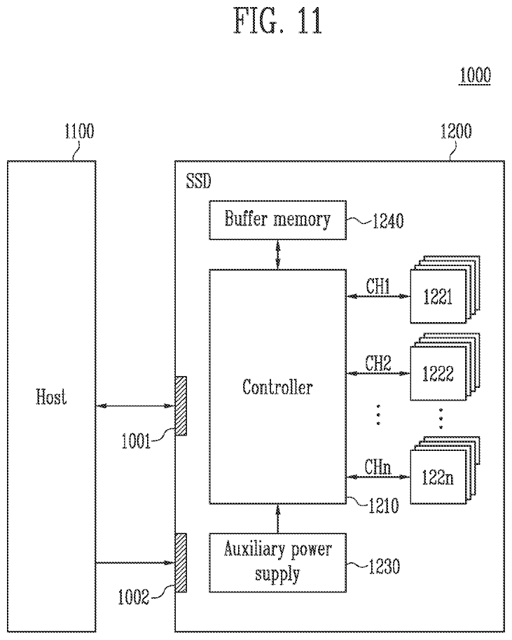

FIG. 11 is a diagram illustrating a solid state drive (SSD) system to which a semiconductor memory device according to the present disclosure is applied.

Referring to FIG. 11, an SSD system 1000 may include a host 1100 and an SSD 1200. The SSD 1200 may exchange a signal with the host 1100 through a signal connector 1001, and may receive power through a power connector 1002. The SSD 1200 may include a controller 1210, a plurality of semiconductor memory devices 1221 to 122n, an auxiliary power supply 1230, and a buffer memory 1240.

The controller 1210 may control the plurality of semiconductor memory devices 1221 to 122n in response to a signal received from the host 1100. In an embodiment, the signal may include signals based on the interfaces of the host 1100 and the SSD 1200. For example, the signal may be a signal defined by at least one of interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

The plurality of semiconductor memory devices 1221 to 122n may store data, and may each include a plurality of nonvolatile memory cells. Each of the plurality of semiconductor memory devices 1221 to 122n may be configured in the same manner as the semiconductor memory device 100 illustrated in FIG. 1.

The auxiliary power supply 1230 may be electrically coupled to the host 1100 through the power connector 1002. The auxiliary power supply 1230 may be supplied with a supply voltage from the host 1100, and may be charged. The auxiliary power supply 1230 may supply the supply voltage of the SSD 1200 when the supply of power from the host 1100 is not smoothly performed. In an embodiment, the auxiliary power supply 1230 may be located inside the SSD 1200 or located outside the SSD 1200. For example, the auxiliary power supply 1230 may be located on a main board, and may also provide auxiliary power to the SSD 1200.

The buffer memory 1240 functions as a buffer memory of the SSD 1200. For example, the buffer memory 1240 may temporarily store data received from the host 1100 or data received from the plurality of semiconductor memory devices 1221 to 122n, or may temporarily store metadata (e.g., mapping tables) of the plurality of semiconductor memory devices 1221 to 122n. The buffer memory 1240 may include volatile memories, such as a DRAM, SDRAM, DDR SDRAM, and LPDDR SDRAM, or nonvolatile memories, such as an FRAM, ReRAM, STT-MRAM, and PRAM.

Various embodiments of the present disclosure may improve 5 the reliability of the read operation of semiconductor memory device.

What is claimed is:

1. A semiconductor memory device, comprising:
a first string group including a plurality of first memory strings connected in parallel between a bit line and a source line; and
a second string group including a plurality of second memory strings connected in parallel between the bit line and the source line,
wherein each of the plurality of first memory strings and the plurality of second memory strings includes at least one down source select transistor, at least one first up source select transistor, and at least one second up source select transistor, and
wherein the at least one first up source select transistor of each of the plurality of first memory strings is programmed to a first state, and the at least one first up source select transistor of each of the plurality of second memory strings is programmed to a second state.

2. The semiconductor memory device according to claim 1, wherein the at least one second up source select transistor of each of the plurality of first memory strings is programmed to the second state, and the at least one second up source select transistor of each of the plurality of second memory strings is programmed to the first state.

3. The semiconductor memory device according to claim 1, wherein the first state is an erase state and the second state is a program state.

4. The semiconductor memory device according to claim 1, wherein a coding data value of the at least one first up source select transistor and the at least one second up source select transistor of the first string group is different from a coding data value of the at least one first up source select transistor and the at least one second up source select transistor of the second string group.

5. The semiconductor memory device according to claim 1, wherein:
each of the plurality of first memory strings and the plurality of second memory strings includes a drain select transistor coupled to the bit line, and
the drain select transistors of the plurality of first memory strings and the plurality of second memory strings are electrically coupled to different drain select lines, respectively.

6. The semiconductor memory device according to claim 1, wherein:
at least one down source select transistor of the plurality of first memory strings and at least one down source select transistor of the plurality of second memory strings share one down source select line,
at least one first up source select transistor of the plurality of first memory strings and at least one first up source select transistor of the plurality of second memory strings share one first up source select line, and
at least one second up source select transistor of the plurality of first memory strings and at least one second up source select transistor of the plurality of second memory strings share one second up source select line.

7. The semiconductor memory device according to claim 1, wherein the plurality of first memory strings and the plurality of second memory strings are alternately arranged.

8. A method of operating a semiconductor memory device including a plurality of first memory strings and a plurality of second memory strings, each of the first and second memory strings are connected in parallel between a bit line and a source line, each of the first and second memory strings including at least one first up source select transistor and at least one second up source select transistor which are connected in series, comprising:
programming the at least one second up source select transistor of the plurality of first memory strings to a first state;
programming the at least one second up source select transistor of the plurality of second memory strings to a second state;
programming the at least one first up source select transistor of the plurality of first memory strings to the second state; and
programming the at least one first up source select transistor of the plurality of second memory strings to the first state,
wherein the at least one first up source select transistor of the plurality of first memory strings and the at least one first up source select transistor of the plurality of second memory strings are programed based on a first up source select line, and
wherein the at least one second up source select transistor of the plurality of first memory strings and the at least one second up source select transistor of the plurality of second memory strings are programed based on a second up source select line.

9. The method according to claim 8, wherein each of the first and second memory strings further comprises at least one drain select transistor connected to the bit line, and
wherein programming the second up source select transistors of the first and second memory strings, comprises:
applying a program-enable voltage to the bit line;
applying a turn-off voltage to first drain select lines coupled to the drain select transistors of the plurality of first memory strings, and applying a turn-on voltage to second drain select lines coupled to the drain select transistors of the plurality of second memory strings; and
applying a program voltage to the second up source select line, and applying a pass voltage to the first up source select line.

10. The method according to claim 8, wherein each of the first and second memory strings further comprises at least one drain select transistor connected to the bit line, and a plurality memory cells connected between the at least one drain select transistor and the at least one first up source select transistor, and
wherein programming the first up source select transistors of the first and second memory strings comprises:
applying a program-enable voltage to the bit line;
applying a turn-on voltage to first drain select lines coupled to drain select transistors of the plurality of first memory strings, and applying a turn-off voltage to second drain select lines coupled to drain select transistors of the plurality of second memory strings; and
applying a program voltage to the first up source select line and applying a pass voltage to the second up source select line.

11. The method according to claim 8, wherein the first state includes programing data “1” to the at least one first up source transistor or the at least one second up source transistor, and
the second state includes programing data “0” to the at least one first up source transistor or the at least one second up source transistor.

12. The method according to claim 8, wherein a coding value of the first up source select transistors and the second up source select transistors of the plurality of first memory strings is programmed to be different from a coding value of the first up source select transistors and the second up source select transistors of the plurality of second memory strings.

13. The method according to claim 8, wherein the plurality of first memory strings and the plurality of second memory strings are alternately arranged.

14. A semiconductor memory device, comprising:
a plurality of first memory strings connected in parallel between a bit line and a source line; and
a plurality of second memory strings connected in parallel between the bit line and the source line,
wherein each of the plurality of first memory strings and the plurality of second memory strings includes at least one down source select transistor, at least one first up source select transistor, and at least one second up source select transistor which are connected in series,
wherein at least one down source select transistor of the plurality of first memory strings and at least one down source select transistor of the plurality of second memory strings share one down source select line, and
wherein at least one first up source select transistor of the plurality of first memory strings shares a first up source select line, and at least one first up source select transistor of the plurality of second memory strings shares a second up source select line.

15. The semiconductor memory device according to claim 14, wherein the at least one second up source select transistor of the plurality of first memory strings shares a third up source select line, and the at least one second up source select transistor of the plurality of second memory strings shares a fourth up source select line.

16. The semiconductor memory device according to claim 15, wherein the at least one first up source select transistor of each of the plurality of first memory strings is programmed to a first state, and the at least one first up source select transistor of each of the plurality of second memory strings is programmed to a second state being.

17. The semiconductor memory device according to claim 16, wherein the first state is an erase state in which a threshold voltage is lower than a set level, and the second state is a program state in which the threshold voltage is equal to or greater than the set level.

18. A semiconductor memory device, comprising:
first to fourth memory strings connected in parallel between a bit line and a source line,
wherein each of the first to fourth memory strings includes:
at least one down source select transistor, at least one first up source select transistor, and at least one second up source select transistor which are connected in series,
wherein the down source select transistors of the first memory string and the second memory string share an even down source select line, and the down source select transistors of the third memory string and the fourth memory string shares an odd down source select line, and
wherein the first up source select transistors of the first to fourth memory strings are controlled by a first up source select line, and
wherein the second up source select transistors of the first to fourth memory strings are controlled by a second up source select line.

19. The semiconductor memory device according to claim 18, wherein:
the second up source select transistors of the first memory string and the third memory string are programmed to a first state,
the second up source select transistors of the second memory string and the fourth memory string are programmed to a second state different from the first state,
the first up source select transistors of the first memory string and the third memory string are programmed to the second state, and
the first up source select transistors of the second memory string and the fourth memory string are programmed to the first state.

20. The semiconductor memory device according to claim 19, wherein the first state is an erase state in which a threshold voltage is lower than a set level, and the second state is a program state in which the threshold voltage is equal to or higher than the set level.

21. A semiconductor memory device, comprising:
a first string group including at least one first memory string connected in parallel between a bit line and a source line; and
a second string group including at least one second memory string connected in parallel between the bit line and the source line,
wherein the at least one first memory string and the at least one second memory string each include at least one down source select transistor, at least one first up source select transistor, and at least one second up source select transistor, and
wherein the at least one first up source select transistor of the at least one first memory string is programmed to a first state, and the at least one first up source select transistor of the at least one second memory string is programmed to a second state.
